(19) United States
(12) Patent Application Publication
(10) Pub. No.: US 2026/0011629 A1
(43) Pub. Date: Jan. 8, 2026

(54) SUBSTRATE WITH STEPPED CONDUCTIVE LAYER SURFACE

(71) Applicant: SEMICONDUCTOR COMPONENTS INDUSTRIES, LLC, Scottsdale, AZ (US)

(72) Inventors: XinCheng JIN, Suzhou (CN); XiaoMin SHI, Suzhou (CN); AnAn XING, Suzhou (CN); ChengHe XU, Suzhou (CN); Keunhyuk LEE, Suzhou (CN)

(73) Assignee: SEMICONDUCTOR COMPONENTS INDUSTRIES, LLC, Scottsdale, AZ (US)

(21) Appl. No.: 18/762,152

(22) Filed: Jul. 2, 2024

(51) Int. Cl. H01L 23/498; H01L 23/31; H01L 23/495

(52) U.S. Cl. CPC H01L 23/49822; H01L 23/3114; H01L 23/49506; H01L 23/49811

(57) ABSTRACT

A substrate includes a base plate made of an insulating material, a first electrically conductive layer disposed on a first side of the base plate, and a second electrically conductive layer disposed on a second side of the base plate. The first electrically conductive layer has a stepped surface, the stepped surface including a plurality of steps at different heights above the base plate.

### TECHNICAL FIELD

This description relates to packaging of semiconductor die and integrated circuits.

### BACKGROUND

Integrated circuit packaging is the final stage of semiconductor device fabrication, in which the semiconductor die, or dies are encapsulated in a supporting case that prevents physical damage and corrosion. The case, known as a package, supports the electrical contacts which connect the semiconductor devices to a circuit board. An integrated circuit package or semiconductor device package includes a metal, plastic, glass, or ceramic casing containing one or more semiconductor devices or integrated circuits. Individual components are fabricated on semiconductor wafers (commonly silicon, or silicon carbide wafers) before being diced into die, tested, and packaged. The package provides a means for connecting the semiconductor devices or integrated circuits to the external environment, such as a printed circuit board, via leads such as lands, balls, or pins and provides a means for protection against threats such as mechanical impact, chemical contamination, and/or light exposure. An example package may include multiple semiconductor die mounted on a substrate. For some applications (e.g., inverter or other circuit applications) to dissipate heat that may be generated in the semiconductor device package, the package can be surface mounted on a heat sink block or a metal casing of an application component or module (e.g., inverter module) itself. With an increasing demand for high-performance integrated circuits, new improvements are needed in packaging technologies to improve the performance and reliability of integrated circuits.

### SUMMARY

In a general aspect, a substrate includes a base plate made of an insulating material, a first electrically conductive layer disposed on a first side of the base plate, and a second electrically conductive layer disposed on a second side of the base plate. The first electrically conductive layer has a stepped surface, the stepped surface including a plurality of steps at different heights above the ceramic base plate.

In a general aspect, a method included disposing an electrically conductive layer on a back side of a ceramic base plate, disposing a first electrically conductive layer having a first thickness on a front side of the ceramic base plate, disposing a second electrically conductive layer having a second thickness on a portion of a top of the first electrically conductive layer, and disposing a third electrically conductive layer having a third thickness on a portion of a top of the second electrically conductive layer.

In a general aspect, a method includes disposing a first semiconductor die on a first step having a first width at a first height in a substrate having a stepped metal surface, disposing a second semiconductor die on an adjacent second step having a second width at a second height in the substrate, and disposing a third semiconductor die on an adjacent third step having a third width at a third height in the substrate. The method further included forming a first electrical connection between the first semiconductor die disposed on the first step and the second semiconductor die disposed on the adjacent second step, and forming a second electrical connection between the second semiconductor die disposed on the adjacent second step and the third semiconductor die disposed on the adjacent third step.

In a general aspect, a package includes a first semiconductor die disposed on a first step having a first width at a first height in a substrate having a stepped metal surface, a second semiconductor die disposed on an adjacent second step having a second width at a second height in the substrate, and a third semiconductor die disposed on an adjacent third step having a third width at a third height in the substrate. The package further includes a first electrical connection between the first semiconductor die disposed on the first step and the second semiconductor die disposed on the adjacent second step, and a second electrical connection between the second semiconductor die disposed on the adjacent second step and the third semiconductor die disposed on the adjacent third step.

The details of one or more implementations are set forth in the accompanying drawings and the description below. Other features will be apparent from the description and drawings, and from the claims.

### BRIEF DESCRIPTION OF THE DRAWINGS

FIG. 1A illustrates a cross-sectional view an example ceramic-metal integrated (CMI) substrate having a stepped surface.

FIG. 1B illustrates a top perspective view of the example ceramic-metal integrated (CMI) substrate of FIG. 1A.

FIG. 2 illustrates an example integrated circuit (IC) package that includes various semiconductor dies mounted on a CMI substrate.

FIG. 3 illustrates a cross sectional view of an example IC package.

FIG. 4 illustrates an example method of fabricating a CMI substrate with a stepped surface.

FIGS. 5A through 5E illustrate cross-sectional views of a substrate through multiple stages of a substrate fabrication process (e.g., the method of FIG. 4).

FIG. 6 pictorially illustrates an alternate method of disposing a one-piece metal layer on a front side FS of a ceramic base plate in a single step.

FIG. 7 illustrates an example method for fabricating an IC package.

### DETAILED DESCRIPTION

An integrated circuit (IC) package (e.g., a semiconductor device package) includes at least one semiconductor die mounted on a lead frame structure that includes leads providing external electrical connections (external to the package) for individual devices or integrated circuits in the semiconductor die. The semiconductor die can be mounted on a paddle or flag in the leadframe structure using a solder or a conductive adhesive. Further, device contact pads on the semiconductor die are electrically connected using, for example, wire bonds (e.g., aluminum or copper wire bonds) to respective ones of the leads. The leads, which extend to an outside of the package body, form external terminal pins that can be used to mount the package on a printed circuit board or terminal strip. In example implementations, the terminal pins can be installed in sockets or soldered to a printed circuit board (PCB) or terminal strip.

For power applications (e.g., automotive applications), the IC package (hereinafter power module) may include silicon carbide transistors, gallium nitride devices, or insulated gate bipolar transistor (IGBT), fast recovery diode (FRD), or other devices.

In example implementations, a power semiconductor device may be mounted (e.g., surface mounted) on an electronic power substrate in the power module.

The substrate (e.g., electronic power substrate) includes a layer made of insulating material. The substrate can be an insulating substrate. The substrate can be made of an insulating material. The insulating substrate may, for example, be a ceramic substrate, an elastomeric substrate, an organic substrate, a phenolic substrate, or a printed circuit board (PCB) made of fiberglass reinforced epoxy resin laminate (e.g., FR-4) material, etc. A first conductive material (e.g., electrically conductive material) layer may be integrated with (or attached to) one side of the insulating substrate and a second conductive material layer may be integrated with (or attached to) a second side of the insulating substrate. In example implementations, the first conductive material layer and the second conductive material layers may, for example, be an electrically conductive layer such as a metal layer. The first conductive material and or the second conductive material layer may be patterned to form circuit traces and may include pads or areas to which heat sinks can be attached.

In an example implementation, the electronic power substrate includes a ceramic substrate. The ceramic substrate may be metalized with metal layers integrated or attached to sides of the ceramic substrate to form a ceramic-metal integrated (CMI) substrate. The CMI substrate may, for example, be a direct bonded copper (DBC) substrate, or an advanced metal brazing (AMB) substrate, with metal layers that are plated, bonded, or formed on each side of a ceramic substrate in the power module. The DBC can be referred to as a direct bonded metal (DBM) if a different metal other than copper (or an alloy thereof) is used. In some implementations, one or more electrically conductive layers coupled to a substrate made of an insulating material can be any type of metal layer.

In some implementations, DBC substrates are used in some power modules, because of their very good thermal conductivity. In some implementations, a DBC substrate is composed of a ceramic oxide substrate (baseplate) with a layer of copper coupled to one or both sides by, for example, a high-temperature oxidation process (e.g., the copper and baseplate are heated to a carefully controlled temperature in an atmosphere of nitrogen containing about 30 ppm of oxygen: under these conditions, a copper-oxygen eutectic forms which bonds successfully both to copper and the ceramic oxide baseplate). In some implementations, the top copper layer can be pre-formed prior to firing or chemically etched using printed circuit board technology to form traces of an electrical circuit, while the bottom copper layer can be maintained as a solid layer. In some implementations, the bottom copper layer can function as, for example, a heat sink.

In some implementations, an AMB substrate has electrical properties similar to that of DBC substrate. In some implementations, an AMB substrate consists of a metal foil (e.g., a copper foil) soldered to the ceramic substrate using solder paste and high temperatures (800° C.-1000° C.) under vacuum.

In example implementations, the bottom copper layer of the DBC substrate (or of the AMB substrate) can be attached to a heat spreader or a heat sink using metallurgical joining techniques such as soldering or sintering. In some example implementations, silver sintering techniques may be used to attach the bottom copper layer of the DBC substrate (or of the AMB substrate) to a surface of the heat spreader or the heat sink.

In example implementations, the IC package (e.g., a power module) can be a hybrid device package that includes a semiconductor die or a plurality of semiconductor dies that are integrated onto to a unifying electronic power substrate (e.g., a ceramic substrate, a DBC substrate, an AMB substrate, an elastomeric substrate, an organic substrate, a phenolic substrate, or a PCB/FR-4 substrate). The different semiconductor dies may, for example, be fabricated on different semiconductor wafers or materials. For example, the plurality of semiconductor dies in the IC package may include a first die formed using a silicon (Si) material and a second die formed using a silicon carbide (SiC) material. In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of the electronic power substrate. The first of the plurality of semiconductor dies may be also connected to lead frame posts by electrical connections such as wire bonds.

In some implementations, a wire bond may form a loop (e.g., a vertical loop) that extends from a contact pad on the first semiconductor die to a contact pad on the second semiconductor die or to a post in a lead frame structure. The term wire loop herein may refer to a geometric shape of a piece of wire used in a wire bond. The wire loop may, for example, have an oval, ellipsoidal, circular or triangular shape. A loop height is measured from a top surface of the die to the peak of the wire loop in a vertical direction. In some instances, a wire bond may extend from a contact pad on the first semiconductor die to a lead post on a lead frame. In some instances, a wire bond may extend from a contact pad on the first semiconductor die to a pad on a conductive trace on a front side of the substrate.

Market requirements (e.g., electrical vehicle (EV) market requirements) dictate that the power module have higher current and voltage capabilities and further include additional electrical functions. In order to meet these requirements, there is a need to include more components (e.g., insulated-gate bipolar transistor (IGBT) dies, fast recovery diode (FRD) dies, negative temperature coefficient (NTC) thermistors, capacitors, sensors etc.) in the power module. Existing electronic power substrates (e.g., ceramic-metal integrated substrates) are planar (e.g., flat). When all components (dies) of the power module are directly disposed (e.g., bonded) on a planar substrate, there can be a big downset between the lead frame and die surfaces. Further, the electrical connections (e.g., wire bonds) connecting the signal leads to the contact pads on the various semiconductor die may be long because of the big downset between the lead frame and die surfaces. Further, thinner wire may be used for the wire bonds to match the smaller pad opening on the IC dies. This configuration of the wire bonds can result in wire clutter causing wire sweeping and shorting of one or more of the wire bonds.

Loop height of a wire is one of the most critical aspects of bonding (e.g., wire bonding, bonding using a conductor such as a wire) as it affects both performance and reliability of the device. The wire loop cannot be too high, since excessively high wire loops can result in exposed wire, wire sweep and/or wire-to-wire shorting that can cause electrical yield loss. On top of that, long wires can also limit and degrade the electrical performance due to higher resistance across the whole wire span. On the other hand, wire loop height also cannot be too low, as it indicates that the wire had been excessively pulled down by the bonding tool from a ball bond to the second bond. Low wire loop height makes the wire too tight putting an enormous stress on the wire neck or wire heel, leading to package reliability problems.

In accordance with the principles of the present disclosure, an example electronic power substrate has a non-planar surface. The non-planar surface may be aa stepped or a terraced surface, formed, for example, by the first conductive material layer attached to one side of the insulating substrate in the electronic power substrate.

An example IC package includes semiconductor die disposed on various steps or terraces of the electronic power substrate surface. The placement of the semiconductor die on the stepped or terraced surfaces may be configured to reduce the lengths of the required wire bonds and avoid wire sweeping of longer wire bonds and also avoid shorting of the wire bonds.

The example electronic power substrate with the stepped or terraced surface may, for example, be a CMI substrate. The CMI substrate may be a DBC or an AMB substrate with a metal layer (e.g., a copper layer) disposed on each side (e.g., a front side and a backside) of a ceramic baseplate. The ceramic base plate may, for example, be made of alumina (Al₂O₃), aluminum nitride (AlN) or silicon nitride (Si₃N₄). The metal layer disposed on each side may be either bonded or brazed to the ceramic base plate.

In example implementations, the metal layer on the frontside of the ceramic baseplate may have a stepped surface S with two or more steps formed in it. The steps may be staircase-like steps or shelves formed by strips of the metal layer attached to the ceramic baseplate. The staircase-like steps or shelves may have different thicknesses (or heights above the ceramic baseplate).

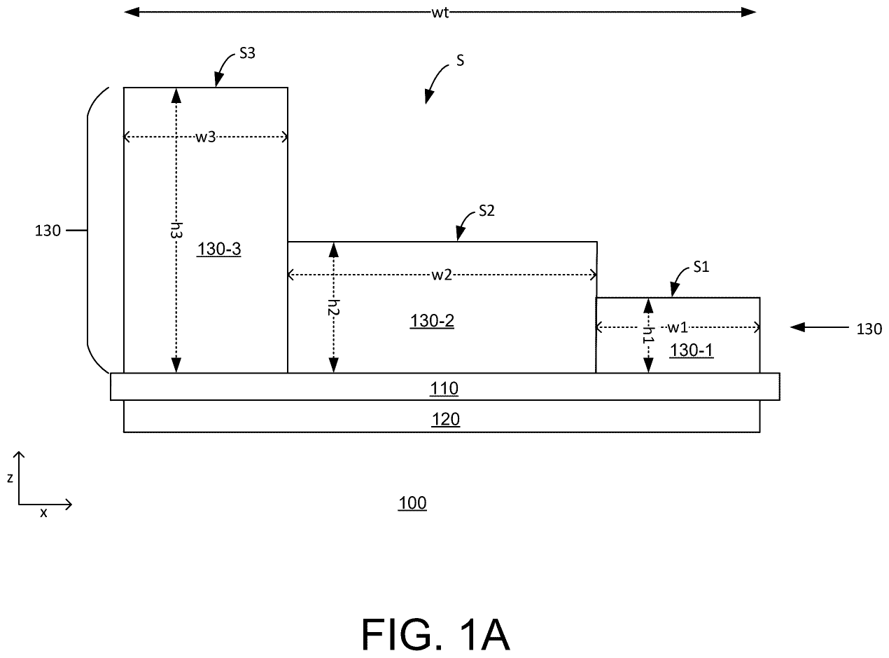

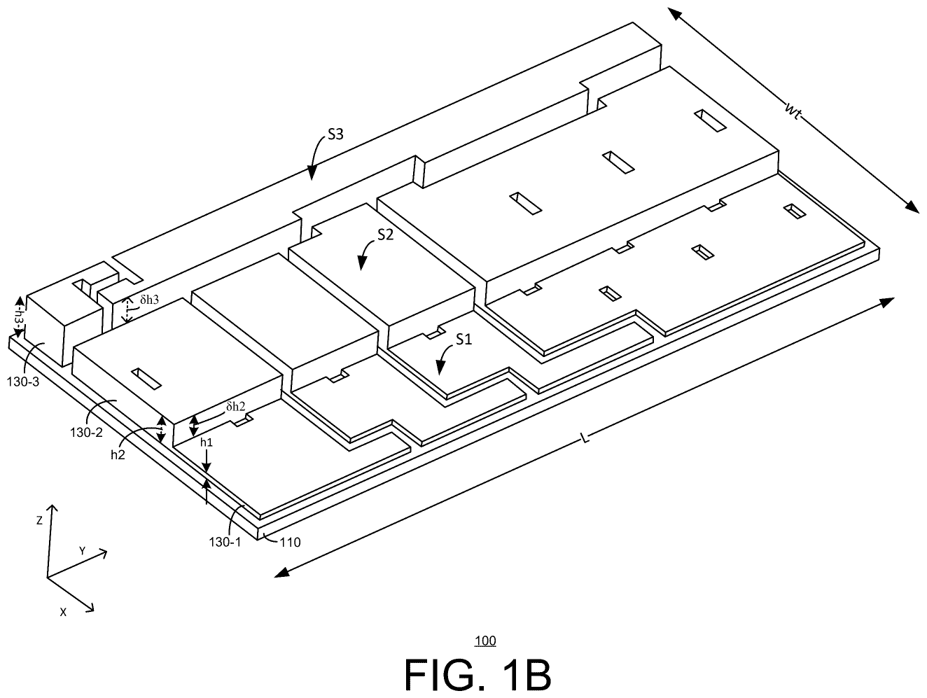

FIGS. 1A and 1B show an example electronic power substrate (e.g., CMI substrate 100) with a stepped surface S. CMI substrate 100 includes a metal layer 120 disposed on a backside of a ceramic base plate 110, and a metal layer 130 with three steps (e.g., S1, S2 and S3) formed in it disposed on a frontside of ceramic base plate 110. Ceramic base plate 110 may have a rectangular shape with, for example, a width wt (e.g., in the x direction). Step S1 in metal layer 130 may be formed by a strip 130-1 of metal layer 130 having width w3 (in the x direction) and a height h1 (in the z direction) above the ceramic base plate 110; step S2 in metal layer 130 may be formed by a strip 130-2 of metal layer 130 having width w2 (in the x direction) and a height h2 (in the z direction) above the ceramic base plate 110; and step S3 in metal layer 130 may be formed by a strip 103-3 of metal layer 130 having width w3 (in the x direction) and a height h3 (in the z direction) above the ceramic base plate 110. In example implementations, height h3 may be greater than height h2, and height h2 may be greater than height h1. In some example implementations, height h3 may be about 1.0 mm or greater, and a difference 8h3 (FIG. 1B) in the heights h3 and h2 may be about 0.4 mm to 0.6 mm. Further, a difference 8h2 (FIG. 1B) in the heights h2 and h1 may be about 0.3 mm to 0.5 mm.

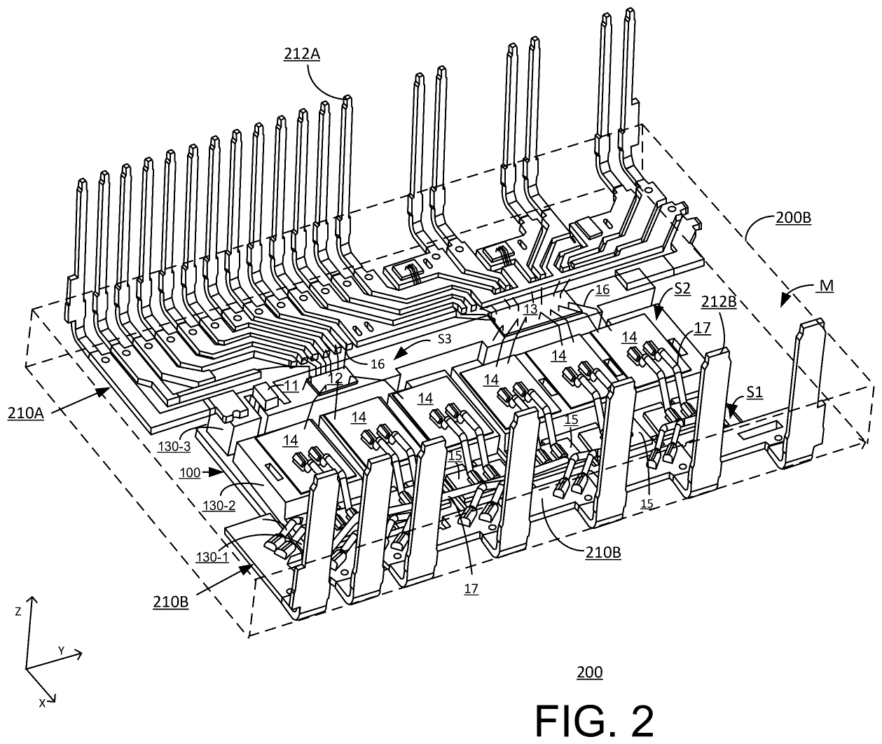

Steps S1, S2, and S3 in CMI substrate 100 may have planar surfaces on which die attach pads (not shown in FIGS. 1 and 1B) are formed (e.g., by solder or sinter paste). Various semiconductor die (FIG. 2) may be disposed on these die attach pads.

FIG. 2 shows an example IC package 200 including various semiconductor die mounted on CMI substrate 100. The semiconductor die may, for example, include a thermistor 11, a first controller IC chip 12, and a second IC controller chip 13, a first power device die 14 and a second power device die 15.

In example implementations, as shown in FIG. 2, CMI substrate 100 may be coupled to lead frames (e.g., lead frame 210A and lead frame 210B) of IC package 200.

In example implementations, lead frame 210A may be attached to substrate 100 at or above strip 130-3 of metal layer 130. Lead frame 210A may include a plurality of leads 212A that can form, for example, the external signal terminals of IC package 200. Further, lead frame 210B may be attached to substrate 100 at or below strip 130-1 of metal layer 130. Lead frame 210B may include a plurality of leads 212B that can form, for example, the external power terminals of IC package 200.

In example implementations, the semiconductor die disposed on CMI substrate 100 may, for example, include a thermistor 11, a first controller IC chip 12, and a second IC controller chip 13 disposed on step S3 of the surface of the CMI substrate (at height h3 above ceramic base plate 110, FIG. 1A). Further, a first power device die 14 (e.g., an IGBT die may be disposed on step S2 of the surface of the CMI substrate (at height h2 above ceramic base plate 110, FIG. 1A), and a second power device die 15 (e.g., an FRD die) may be disposed on step S1 of the surface of the CMI substrate (at height h1 above ceramic base plate 110, FIG. 1A).

Wire bonds (e.g., wire bonds 16) (which could be any type of electrical connection) may be used to electrically connect the semiconductor die (e.g., thermistor 11, first controller IC chip 12, and second controller IC chip 13) disposed on step S3 to the leads 212A of lead frame 210A. Wire bonds 16 may also be used to electrically connect the semiconductor die (e.g., thermistor 11, first controller IC chip 12, and second controller IC chip 13) disposed on step S3 to the semiconductor die (e.g., a first power device die 14) disposed on step S2.

In example implementations, wire bond 16 may include small diameter wire (e.g., copper or gold wire) that are suitable, for example, for carrying low power electrical signals. Wire bonds 16 may extend over the vertical height difference (8h3) between the height (h3) of step S3 and the height (h2) of step S2 (FIG. 1B).

Furthermore, wire bonds (e.g., wire bonds 17) may be used to electrically connect the semiconductor dies (e.g., a first power device die 14) disposed on step S2 to the semiconductor dies (e.g., second power device die 15) disposed on step S1, and to electrically connect the semiconductor dies (e.g., second power device die 15) disposed on step S1 to the plurality of leads 212B in lead frame 210B.

In example implementations, the wire bonds (e.g., wire bond 17) may include larger diameter wire (e.g., aluminum wire) that is suitable, for example, for carrying electrical power. Wire bond 17 may extend over the vertical height difference (δh2) between the height (h2) of step S2 and the height (h1) of step S1 (FIG. 1B).

In some implementations, the semiconductor dies, and other components (e.g., a lead frame substrate) of IC package 200 may be encapsulated in a mold body 200B (e.g., body made of a plastic or an epoxy, etc.). In FIG. 2, mold body 200B is depicted as a rectangular box with edges drawn in dashed lines. Mold body 200B may be made of a plastic and/or an epoxy material M.

In some implementations, pins, or terminals (e.g., leads 212A, leads 212B, etc.) may extend to an outside the IC package 200.

In example implementations, IC package 200 can be a surface-mount package with an exposed copper thermal pad at a bottom of the module. The exposed copper thermal pad may, for example, be formed by a metal layer 120 of the CMI substrate 100 (FIG. 1A) (i.e., the DBC or AMB substrate) on which the semiconductor dies are mounted.

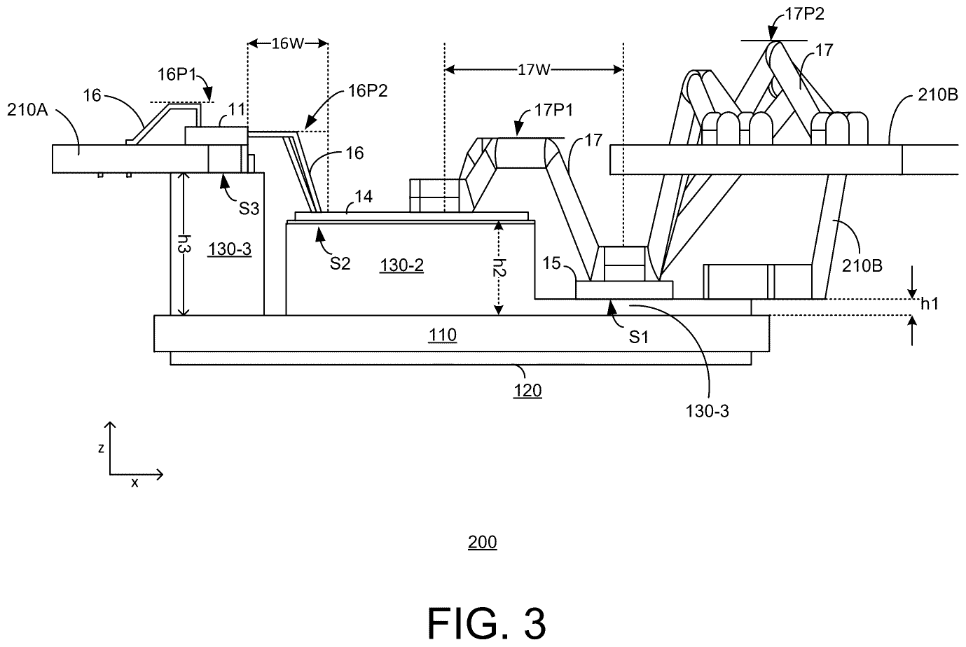

FIG. 3 shows a cross sectional view of IC package 200 with wire bonds 16 (e.g., electrical connections) electrically connecting the semiconductor die (e.g., thermistor 11) disposed on step S3 to lead frame 210A, and first power device die 14 disposed on step S2. The wire bonds 16 between thermistor 11 and lead frame 210A may, for example, have a peak vertical loop height 16P1 (in the z direction), and the wire bonds 16 between thermistor 11 and first power device die 14 may, for example, have a peak vertical loop height 16P2 (in the z direction). The wire bonds 16 between thermistor 11 and first power device die 14 may, for example, have a loop width 16W (in the x direction).

FIG. 3 further shows wire bonds 17 electrically connecting the semiconductor die (e.g., a first power device die 14) disposed on step S2 to the semiconductor dies (e.g., second power device die 15) disposed on step S1. Further, wire bonds 17 may electrically connect the semiconductor die 15 disposed on step S1 to lead frame 210B. The wire bonds 17 between first power device die 14 disposed on step S2 and the second power device die 15 disposed on step S1 may, for example, have a peak vertical loop height 17P1 (in the z direction), and the wire bonds 17 between the second power device die 15 disposed on step S1 and lead frame 210B may, for example, have a peak vertical loop height 17P2 (in the z direction). The wire bonds 17 between the first power device die 14 disposed on step S2 and the second power device die 15 disposed on step S1 may, for example, have a loop width 17W (in the x direction).

Methods for fabricating CMI substrate 100 with a stepped surface S (such as shown in FIG. 1A and FIG. 1B) may involve multiple steps disposing multiple metal layers (e.g., of the same thickness) sequentially on a ceramic base plate, or a single step disposing a pre-shaped metal layer to the ceramic base plate. The pre-shaped metal layer may include portions of different thicknesses corresponding to the heights of the different steps (e.g., steps S1, S2, and S3) in the surface of the substrate.

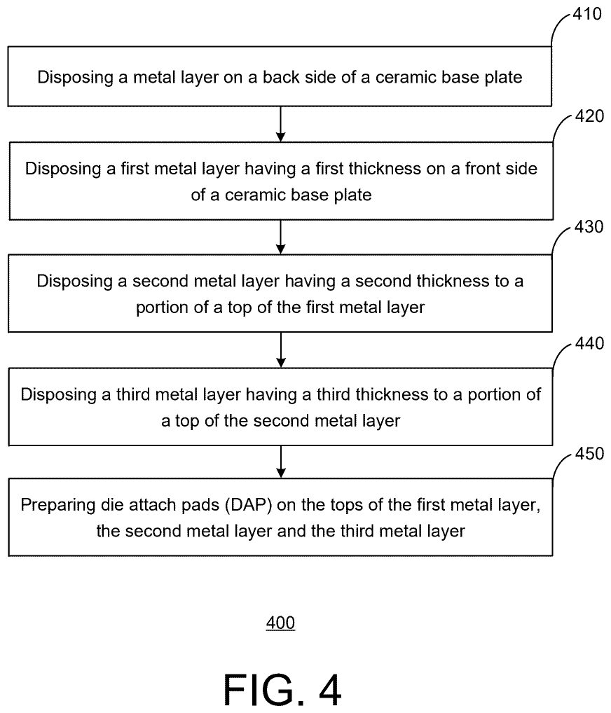

FIG. 4 illustrates an example method 400 for fabricating CMI substrate 100 with a stepped surface S. Method 400 includes disposing a metal layer on a back side of a ceramic base plate (410), and disposing a first metal layer having a first thickness on a front side of the ceramic base plate (420). The first metal layer having the first thickness may form the first step S1 of CMI substrate 100. Method 400 may further include disposing a second metal layer having a second thickness on a portion of a top of the first metal layer (430). The second metal layer having the second thickness may form the second step S2 of CMI substrate 100. Method 400 may further include disposing a third metal layer having a third thickness on a portion of a top of the second metal layer (440). A top of the third metal layer having the third thickness may form the third step S3 of CMI substrate 100.

In method 400, the disposing of the various metal layers (e.g., disposing the metal layer on the backside of the ceramic base plate, disposing the first metal layer on the front side the ceramic base plate, disposing the second metal layer, and disposing the third metal layer) may include bonding, brazing, or soldering processes.

In preparation for packaging semiconductor dies in a package, method 400 may further include preparing die attach pads (DAP) on the tops of the first metal layer, the second metal layer and the third metal layer of the CMI substrate (450). Preparing die attach pads may, for example, include applying solder paste to designated areas of the DAP on the tops of the first metal layer, the second metal layer and the third metal layer of the CMI substrate (e.g., CMI substrate 100).

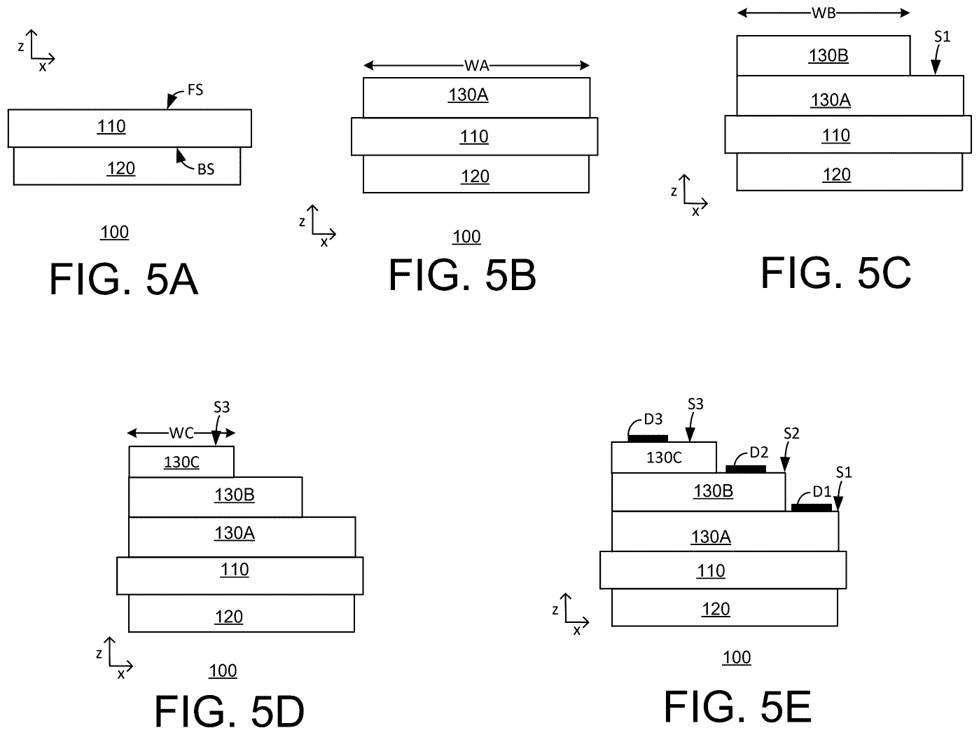

FIGS. 5A through 5E illustrate plan views or cross-sectional views of a substrate through multiple stages of a substrate fabrication process (e.g., the method of FIG. 4), in accordance with the principles of the present disclosure.

FIG. 5A shows, for example, substrate 100 including a ceramic base plate (e.g., base plate 110). A metal layer 120 is attached (e.g., bonded, sintered, or brazed) to a backside (BS) of base plate 110 at a first stage of the substrate fabrication process.

FIG. 5B shows, for example, substrate 100 at a next stage of the fabrication process. At this stage, metal layer 130A is attached to a front side (FS) of base plate 110. Metal layer 130A may for example, have a width WA (in the x direction).

FIG. 5C shows substrate 100 at a further stage of construction. At this stage of construction, a metal layer 130B is attached (e.g., bonded, sintered, or brazed) to a top of metal layer 130A. Metal layer 130B may have a width WB (in the x direction) that is smaller than the width WA of metal layer 130A. Thus, metal layer 130B may cover only a portion of metal layer 130A. The portion of metal layer 130A not covered by metal layer 130B may form a step (S1) in the surface of substrate 100.

FIG. 5D shows substrate 100 at a further stage of construction. At this stage of construction, a metal layer 130C is attached (e.g., bonded, sintered, or brazed) to a top of metal layer 130B. Metal layer 130C may have a width WC (in the x direction) that is smaller than the width WB of metal layer 130B. Thus, metal layer 130C may cover only a portion of metal layer 130B. The portion of metal layer 130A not covered by metal layer 130B may form a step (S2) in the surface of substrate 100.

A top surface of metal layer 130C may form a step (S3) in the surface of substrate 100.

In example implementations, the thicknesses of the various metal layers (e.g., metal layer 130A, metal layer 130B, and metal layer 130C) used in the fabrication of substrate 100 may be metal layers having the same (or about the same) thickness. In other example implementations, the various metal layers (e.g., metal layer 130A, metal layer 130B, and metal layer 130C) may have different thicknesses in consideration of the desired or targeted heights of steps S1, S2, and S3.

In some example implementations, substrate 100 may be further prepared to receive semiconductor die for packaging. In some example implementations, die attach pads may be prepared on steps S1, S2 and S3 of substrate 100 to receive the semiconductor die. FIG. 5E shows, for example, die attach pads, D1, D1 and D3, formed on steps S1, S2, and S3, respectively. The die attach pads may be prepared by coating designated areas on steps S1, S2 and S3, for example, with a solder paste or other conductive adhesive compounds.

An alternate method for fabricating substrate 100 may use a pre-shaped metal layer including portions of different thicknesses corresponding to the heights of the different steps (e.g. steps S1, S2, and S3) of the substrate. In the alternate method, the individual steps of method 400 of disposing the first metal layer, the second metal layer, and the third metal layer in sequence may be replaced by a single step of disposing the pre-shaped metal layer to the frontside FS of base plate 110.

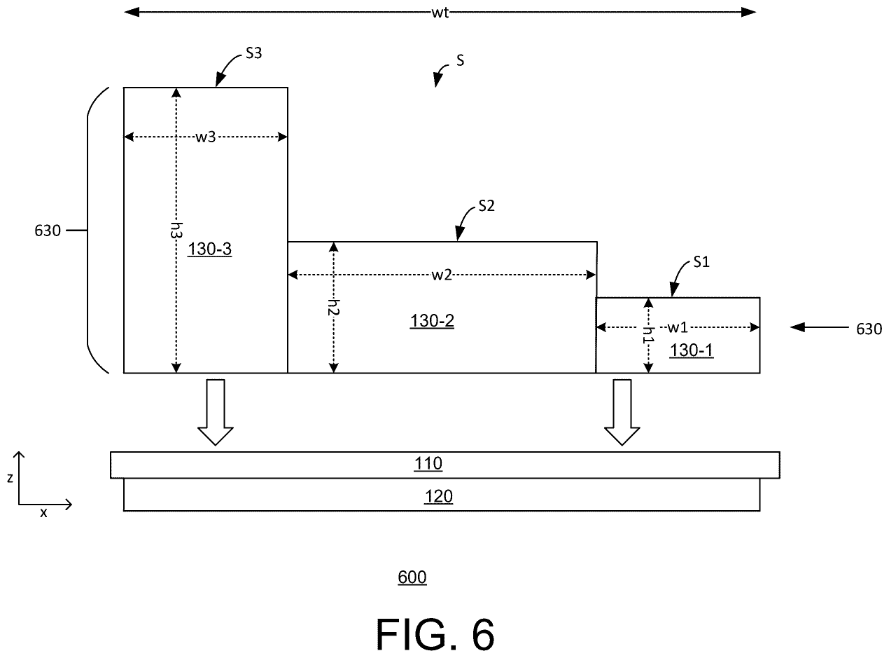

FIG. 6 pictorially illustrates an alternate method 600 of disposing a pre-shaped one-piece metal layer 630 to a front side FS of ceramic base plate 110 in a single step. FIG. 6 shows a pre-shaped one-piece metal layer (e.g., one-piece metal layer 630) being placed on base plate 110 before attachment (e.g., bonding, sintering or brazing). One-piece metal layer 630 (like metal layer 130, FIG. 1A) may include three steps S1, S2 and S3 at respective heights h1, h2 and h3 above base plate 110.

A method for packaging semiconductor dies in an IC package includes disposing a plurality of semiconductor die on a ceramic-metal integrated (CMI) substrate having a plurality of steps in a metal layer above a ceramic base plate. The plurality of steps may form a staircase-like pattern across a width of the substrate with the steps being at different vertical heights above a ceramic base plate. A step having the largest vertical height may be near one end of the substrate and a step with the lowest height may be near an opposite end of the substrate across the width of the substrate. A first lead frame may include a plurality of leads that can form, for example, the external signal terminals of an IC package. A second lead frame may include a plurality of leads that can form, for example, the power terminals of the IC package.

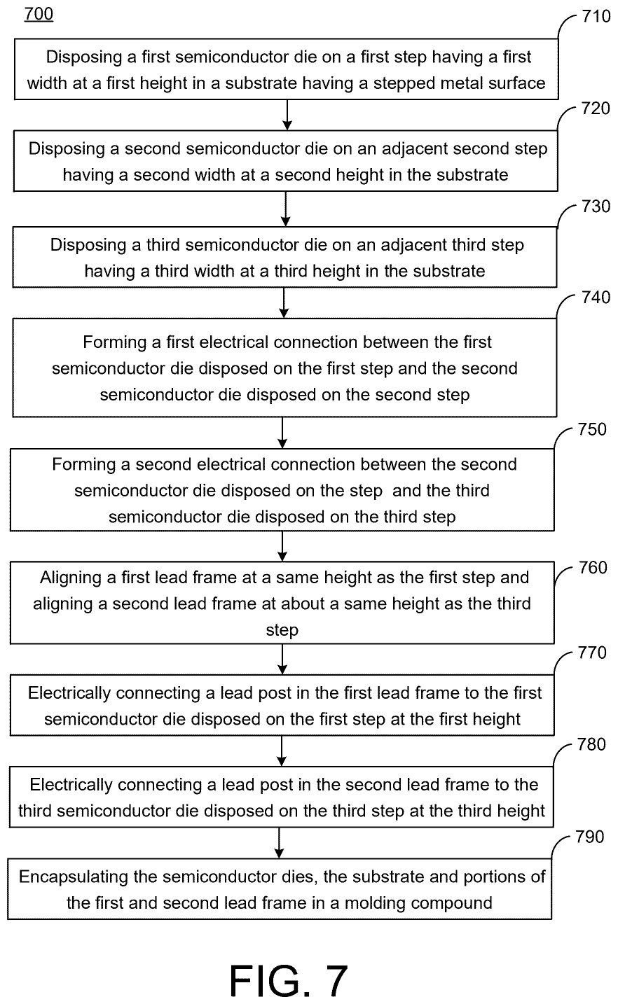

FIG. 7 illustrates an example method 700 for fabricating an IC package. Example method 700 includes disposing a first semiconductor die on a first step having a first width at a first height in a substrate (710), and disposing a second semiconductor die on an adjacent second step having a second width at a second height in the substrate (720). The first height may be greater than the second height. The first semiconductor die, and the second semiconductor may have a height difference proportional to the difference in the first height and the second height. Method 700 may further include disposing a third semiconductor die on an adjacent third step having a third width at a third height in the substrate (730). The third height may be smaller than the second height. The second semiconductor die, and the third semiconductor die may have a height difference proportional to the difference in the second height and the third height.

Method 700 may further include forming a first electrical connection (e.g., forming using an electrical conductor or wire bond) between the first semiconductor die disposed on the first step and the second semiconductor die disposed on the second step (740). The first electrical connection may be made using gold or copper wire. A length of the first electrical connection may be proportional to a height difference in the first height and the second height. A loop width of the first electrical connection may span a distance between the first step and the second step. The loop width of the first electrical connection may be limited and may not extend beyond the first step and the second step (to, for example, the third step). In example implementations, the loop width of the first electrical connection may be less than the combined widths of the first step and the second step.

Method 700 may further include forming a second electrical connection (e.g., forming using an electrical conductor or wire bond) between the second semiconductor die disposed on the second step and the third semiconductor die disposed on the third step (750). The second electrical connection may be made using aluminum or copper wire. A length of the second electrical connection may be proportional to a height difference in the second height and the third height. A loop width of the second electrical connection may span a distance between the second step and the third step. The loop width of the second electrical connection may be limited and may not extend beyond the second step and the third step (to, for example, the first step). In example implementations, the loop width of the second electrical connection may be less than the combined widths of the second step and the third step.

Method 700 may further include disposing a first lead frame at a same (e.g., about a same) height as the first step and a second lead frame at about a same height as the third step (760). Method 700 may include electrically connecting (e.g., wire bonding, bonding using a conductor such as a wire) a lead post in the first lead frame to the first semiconductor die disposed on the first step at the first height (770), and electrically connecting (e.g., wire bonding) a lead post in the second lead frame to the third semiconductor die disposed on the third step at a third height in the substrate (780).

Method 700 further includes encapsulating the semiconductor dies, the substrate and portions of the first and second lead frame in a molding compound (790).

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A substrate, comprising:
a base plate made of an insulating material;
a first electrically conductive layer disposed on a first side of the base plate; and
a second electrically conductive layer disposed on a second side of the base plate,
the first electrically conductive layer having a stepped surface, the stepped surface including a plurality of steps at different heights above the base plate.

2. The substrate of claim 1, wherein the plurality of steps form a stair-case like pattern with a step having a largest height being disposed at one end of the substrate and a step with a lowest height being disposed on an opposite end of the substrate across a width of the substrate.

3. The substrate of claim 1, wherein the plurality of steps includes:
a first step having a first width disposed at a first height above the base plate;
a second step having a second width disposed at a second height above the base plate; and
a third step having a third width disposed at a third height above the base plate.

4. The substrate of claim 1, wherein a surface of each of plurality of steps includes a die attach pad (DAP), the DAP being configured to receive a semiconductor die for attachment to the substrate.

5. The substrate of claim 1, wherein the insulating material is a ceramic material made of alumina (Al₂O₃), aluminum nitride (AlN) or silicon nitride (Si₃N₄).

6. The substrate of claim 1, wherein the first electrically conductive layer has a stepped metal surface made of copper.

7. A method, comprising:
disposing an electrically conductive layer on a back side of a base plate made of an insulating material;
disposing a first electrically conductive layer having a first thickness on a front side of the base plate;
disposing a second electrically conductive layer having a second thickness on a portion of a top of the first electrically conductive layer; and
disposing a third electrically conductive layer having a third thickness on a portion of a top of the second electrically conductive layer.

8. The method of claim 7, wherein disposing the first electrically conductive layer, disposing the second electrically conductive layer, and disposing the third electrically conductive layer include at least one of a bonding process, a soldering process, or a sintering process.

9. The method of claim 7, wherein disposing the first electrically conductive layer, disposing the second electrically conductive layer, and disposing the third electrically conductive layer comprise disposing a pre-shaped electrically conductive layer with a stepped surface on the front side of the base plate.

10. The method of claim 7, further comprising:
preparing at least one die attach pad (DAP) on a top of the first electrically conductive layer, a top of the second electrically conductive layer, and a top of the third electrically conductive layer.

11. The method of claim 10, wherein preparing the at least one DAP includes applying a solder paste to a designated area on the top of the first electrically conductive layer, the top of the second electrically conductive layer, and the top of the third electrically conductive layer.

12. A method, comprising:
disposing a first semiconductor die on a first step having a first width at a first height in a substrate having a stepped surface;
disposing a second semiconductor die on an adjacent second step having a second width at a second height in the substrate;
disposing a third semiconductor die on an adjacent third step having a third width at a third height in the substrate;
forming a first electrical connection between the first semiconductor die disposed on the first step and the second semiconductor die disposed on the adjacent second step; and
forming a second electrical connection between the second semiconductor die disposed on the adjacent second step and the third semiconductor die disposed on the adjacent third step.

13. The method of claim 12, further comprising:
aligning a first lead frame at about a same height as the first step and aligning a second lead frame at about a same height as the adjacent third step;
electrically connecting a lead post in the first lead frame to the first semiconductor die disposed on the first step at the first height; and
electrically connecting a lead post in the second lead frame to the third semiconductor die disposed on the adjacent third step at a third height in the substrate.

14. The method of claim 13, further comprising:
encapsulating the first semiconductor die, the second semiconductor die, the third semiconductor die, the substrate, a portion of the first lead frame, and a portion of the second lead frame in a molding compound.

15. The method of claim 12, wherein the substrate is a ceramic-metal integrated (CMI) substrate with a first electrically conductive layer having a stepped metal surface coupled to a front side of a ceramic base plate, and a second electrically conductive layer coupled to a back side of the ceramic base plate, the ceramic base plate being made of alumina (Al₂O₃), aluminum nitride (AlN) or silicon nitride (Si₃N₄).

16. A package comprising:
a first semiconductor die disposed on a first step having a first width at a first height in a substrate having a stepped surface;
a second semiconductor die disposed on an adjacent second step having a second width at a second height in the substrate;
a third semiconductor die disposed on an adjacent third step having a third width at a third height in the substrate;
a first wire bond between the first semiconductor die disposed on the first step and the second semiconductor die disposed on the adjacent second step; and
a second wire bond between the second semiconductor die disposed on the adjacent second step and the third semiconductor die disposed on the adjacent third step.

17. The package of claim 16, wherein a loop width of the first wire bond is less than the first width of the first step combined with the second width of the adjacent second step.

18. The package of claim 16, wherein a loop width of the second wire bond is less the second width of the adjacent second step combined with the third width of the adjacent third step.

19. The package of claim 16, further comprising:
a first lead frame aligned with the substrate about a same height as the first step; and
a second lead frame aligned with the substrate at about a same height as the adjacent third step.

20. The package of claim 19, further comprising:
a wire bond between a lead post in the first lead frame and the first semiconductor die disposed on the first step at the first height; and
a wire bond between a lead post in the second lead frame and the third semiconductor die disposed on the adjacent third step at a third height in the substrate.

21. The package of claim 19, further comprising:
a molding compound encapsulating the first semiconductor die, the second semiconductor die, the third semiconductor die, the substrate, a portion of the first lead frame, and a portion of the second lead frame.

22. The package of claim 16, wherein the substrate is a ceramic-metal integrated (CMI) substrate with a metal layer having the stepped surface.

23. The package of claim 16, wherein the substrate includes:
a layer of insulating material; and
a first conductive material layer attached to one side of the layer of insulating material, the first conductive material layer forming the stepped surface of the substrate, the stepped surface including a plurality of steps at different heights above the layer made of insulating material.

24. The package of claim 23, wherein the layer of insulating material includes at least one of:
a ceramic substrate, an elastomeric substrate, an organic substrate, a phenolic substrate, or a printed circuit board (PCB) made of fiberglass reinforced epoxy resin laminate (FR-4) material.

25. The package of claim 23, wherein the first conductive material layer includes a metal layer.

26. The package of claim 23, wherein the plurality of steps form a stair-case like pattern with a step having a largest height being disposed at one end of the layer of insulating material and a step with a lowest height being disposed on an opposite end of the layer of insulating material.

27. The package of claim 26, wherein the plurality of steps includes:
a first step having a first width disposed at a first height above the layer of insulating material;
a second step having a second width disposed at a second height above the layer of insulating material; and
a third step having a third width disposed at a third height above the layer of insulating material.
